(19) United States
(12) Patent Application Publication
(10) Pub. No.: US 2026/0184058 A1
(43) Pub. Date: Jul. 2, 2026

(54) METHOD FOR BONDING HEAT SINK IN MULTIPLE NEGATIVE PRESSURE ENVIRONMENT

(71) Applicant: HORNG TERNG AUTOMATION CO., LTD., Kaohsiung City (TW)

(72) Inventor: Wei-chieh WANG, Kaohsiung City (TW)

(73) Assignee: HORNG TERNG AUTOMATION CO., LTD., Kaohsiung City (TW)

(21) Appl. No.: 19/305,782

(22) Filed: Aug. 21, 2025

(30) Foreign Application Priority Data
Dec. 31, 2024 (TW) 113151658

(51) Int. Cl. B32B 37/10; B32B 37/12; H01L 23/00

(52) U.S. Cl. CPC B32B 37/1018; B32B 37/12; B32B 2307/302; B32B 2457/14; H10W 72/07331; H10W 72/07341

(57) ABSTRACT

The present invention provides a method for bonding a heat sink in a multi-negative pressure environment, comprising the following steps placing a workpiece with a retaining wall structure in a lower jig; supplying adhesive to a surface of the workpiece within an area surrounded by the retaining wall structure; using an upper jig to pick up the heat sink and aligning it with the lower jig to form first closed space; evacuating the first closed space to create a first negative pressure environment; positioning the heat sink onto the retaining wall structure to form second closed space; bonding the heat sink to the workpiece, during which at least one gap is formed; continuing to apply pressure to the heat sink, creating a negative pressure within the gap; and restoring negative pressure environments to atmospheric pressure, allowing the adhesive to fill the gap. This method eliminates gaps during bonding.

### CROSS-REFERENCE TO RELATED APPLICATIONS

This application claims priority to Taiwan Application Serial Number 113151658, filed on Dec. 31, 2024, which is incorporated herein by reference.

### FIELD OF INVENTION

The invention relates to a method for bonding a heat sink, particularly to a method for bonding a heat sink in a multi-negative pressure environment, which is used to eliminate bubbles or gaps generated during the bonding process of the heat sink.

### BACKGROUND OF INVENTION

The heat sink bonding and pressing process typically involves first applying a heat dissipation material to a die (for example, along a predetermined path), followed by pressing a heat sink onto the die to ensure even distribution of the heat dissipation material. The heat is dissipated between the die and the heat sink through the high thermal conductivity of the heat dissipation material and its close contact with both the die and the heat sink. However, during the applying or pressing process, air may be trapped in the heat dissipation material, creating gaps that negatively affect heat dissipation.

### SUMMARY OF INVENTION

One object of the present invention is to provide a heat sink bonding method to address the problems existing in the prior art.

According to the aforementioned object a method for bonding a heat sink in a multi-negative pressure environment is provided. The method comprising steps of: placing a workpiece to be processed in a lower jig, wherein a retaining wall structure is provided on a side edge of the workpiece; supplying an adhesive to a surface of the workpiece within an area surrounded by the retaining wall structure; after a suction head of an upper jig picks up the heat sink, moving the upper jig to assemble with the lower jig to form a first closed space, wherein the heat sink and the workpiece are positioned within the first closed space; evacuating the first closed space to create a first negative pressure environment; driving the suction head to move toward the workpiece, and positioning the heat sink to an upper surface of the retaining wall structure, forming a second closed space between the heat sink and the workpiece, wherein the adhesive is positioned within the second closed space; continuing to drive the suction head to move toward the workpiece to compress the retaining wall structure, which causes deformation of the retaining wall structure and forms a second negative pressure environment in the second closed space; continuing to drive the suction head to move toward the workpiece to bond the heat sink to the workpiece, wherein at least one gap is formed between the heat sink and the adhesive; continuing to drive the suction head toward the workpiece to apply pressure to the heat sink after the gap is formed, thereby creating a negative pressure within the gap; and restoring both the first negative pressure environment and the second negative pressure environment to normal atmospheric pressure after bonding the heat sink to the workpiece, allowing the adhesive surrounding the gap to fill the gap.

According to an embodiment of the present invention, a surface of the heat sink is rough, and during the deformation of the retaining wall structure, air in the second closed space can be discharged from between the heat sink and the retaining wall structure.

According to an embodiment of the present invention, the adhesive is a sheet-type adhesive, and an initial height of the retaining wall structure before deformation is lower than a top surface of the sheet-type adhesive.

According to an embodiment of the present invention, the adhesive is a liquid adhesive, and an initial height of the retaining wall structure before deformation is higher than a surface of the liquid adhesive.

According to an embodiment of the present invention, the pressures in both the first negative pressure environment and the second negative pressure environment are lower than the pressure of an external environment, and the pressure in the first negative pressure environment is greater than or equal to the pressure in the second negative pressure environment.

According to an embodiment of the present invention, the adhesive is a sheet-type adhesive, and the step of supplying the adhesive to the surface of the workpiece further includes using the suction head of the upper jig to pick up the sheet-type adhesive to the surface of the workpiece.

According to an embodiment of the present invention, the step of evacuating the first closed space and the step of driving the suction head to move toward the workpiece are performed sequentially or simultaneously.

According to an embodiment of the present invention, the step of placing the workpiece in the lower jig comprises selecting a product fixture corresponding to the size of the workpiece and positioning the product fixture in the lower jig.

According to an embodiment of the present invention, the product fixture comprises a bearing groove, and when the product fixture is positioned in the lower jig by a positioning mechanism, the center of the bearing groove is aligned with the center of the lower jig.

According to an embodiment of the present invention, the positioning mechanism comprises at least two protruding structures and at least two recessed structures corresponding to the protruding structures, wherein the protruding structures are arranged on one of the product fixture and the lower jig, and the recessed structures are arranged on the other of the product fixture and the lower jig.

According to the aforementioned embodiments of the present invention, the method for bonding the heat sink in a multi-negative pressure environment provided by the present invention primarily involves creating two separate negative pressure environments in two closed spaces and applying pressure to the adhesive in these negative pressure environments. This method efficiently resolves the issue of gaps forming between the heat sink and the workpiece, ensuring a high bonding quality. In addition, the design of the retaining wall structure can effectively prevent adhesive overflow, further ensuring the bonding quality. This method is particularly applicable to precision processes, such as those used in semiconductor manufacturing, with advantages such as simplified operation, increased efficiency, and reduced production costs.

### DESCRIPTION OF DRAWINGS

FIG. 1 is a flowchart of a heat sink bonding method in a multi-negative pressure environment, according to an embodiment of the present invention.

FIGS. 2A to 6B are schematic diagrams Illustrating each step of the heat sink bonding method according to an embodiment of the present invention.

FIGS. 7A to 7C are schematic diagrams showing how the gap is filled with the adhesive according to an embodiment of the present invention.

FIG. 8 is an exploded view of a jig assembly according to an embodiment of the present invention.

FIGS. 9A to 9C are schematic diagrams showing different product fixtures according to various embodiments of the present invention.

### DETAILED DESCRIPTION OF PREFERRED EMBODIMENTS

In order to make the objects, features, and advantages of the present invention more comprehensible, preferred embodiments of the present invention will be described in detail below, together with the accompanying drawings. Furthermore, the directional terms used in the present invention, such as up, down, top, bottom, front, back, left, right, inside, outside, side, around, central, horizontal, transverse, vertical, longitudinal, axial, radial, the uppermost layer, or the lowermost layer, etc., are only for reference with respect to the orientations shown in the accompanying drawings. Therefore, these directional terms are used solely for illustrative purposes and are not intended to limit the scope of the present invention.

The present embodiment provides a method for bonding a heat sink in a multi-negative pressure environment, which is primarily used for bonding liquid adhesives, which can effectively eliminate bubbles or gaps that may form during the bonding process, thereby ensuring reliable adhesion between a heat sink, an adhesive, and a workpiece to be processed.

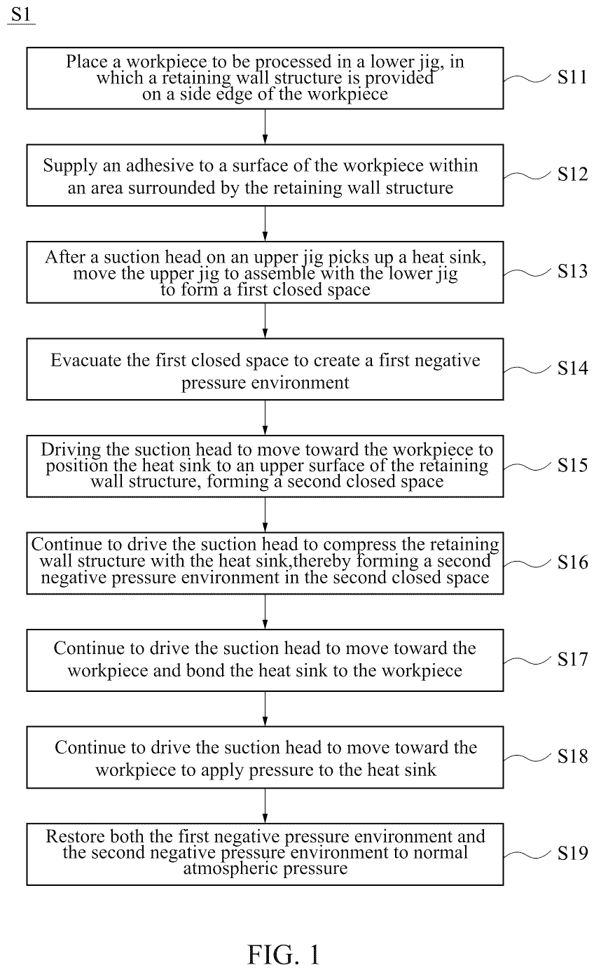

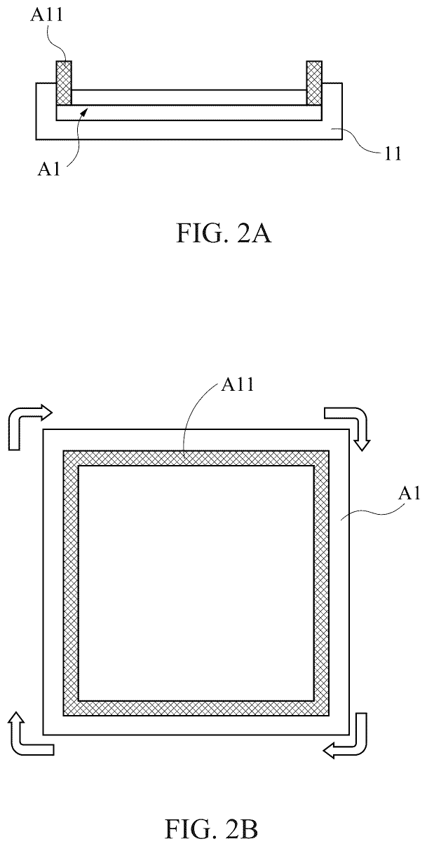

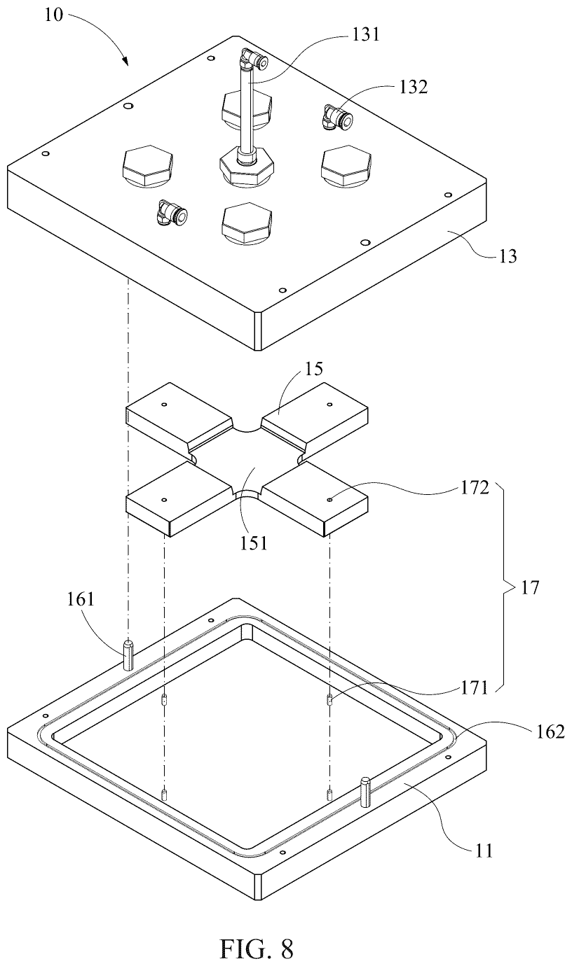

Specifically, as shown in FIGS. 1 to 6B, method S1 for bonding the heat sink in the multi-negative pressure environment of the present embodiment mainly includes the following steps. In one embodiment, the method S1 of the present embodiment can be performed using a jig assembly 10 as shown in FIG. 8, but it is not limited to this. The method S1 can also be performed using other suitable devices. In method S1, step S11 is first performed to place a workpiece to be processed (hereinafter referred to as “workpiece A1”) in a lower jig 11. As shown in FIG. 2A, a retaining wall structure A11 is provided on a side edge of the workpiece A1. In one embodiment, the retaining wall structure A11 is an elastic semi-cured colloid, which can be formed by supplying a colloid along the outer periphery of the workpiece A1 as shown in FIG. 2B.

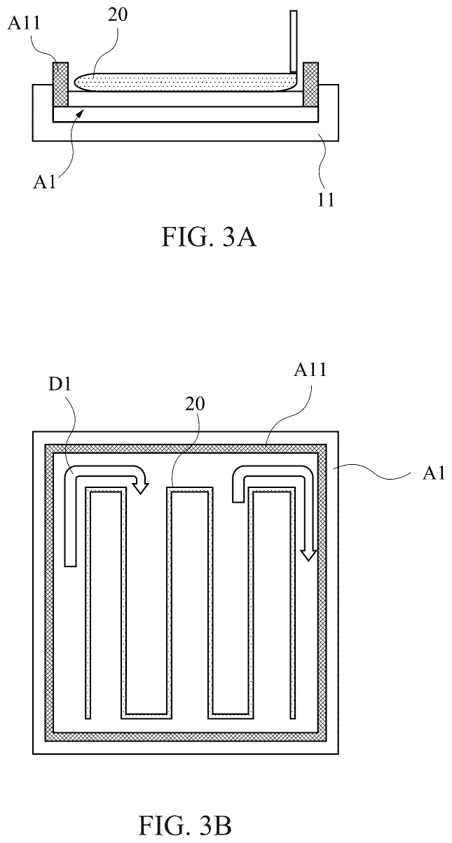

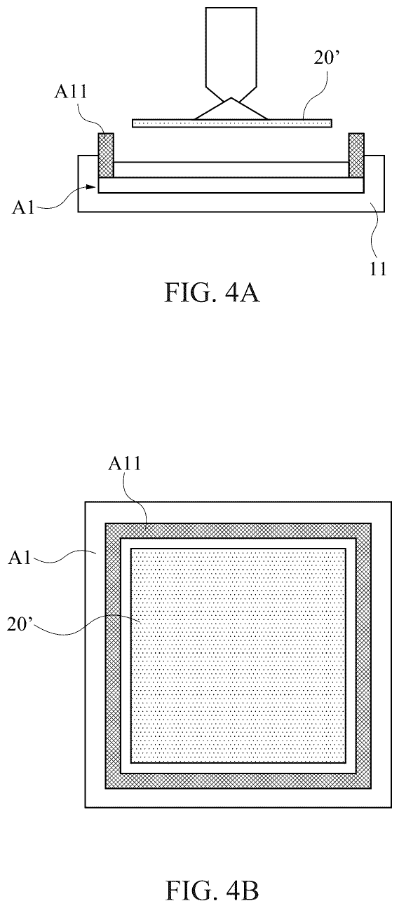

Next, step S12 is performed, as shown in FIG. 3A and FIG. 3B, in an area surrounded by the retaining wall structure A11, adhesive 20 is supplied to a surface of the workpiece A1. In a specific example, the workpiece A1 may be a semiconductor wafer, and the adhesive 20 may be a heat dissipation adhesive having appropriate viscosity to ensure that the heat sink A2 is firmly bonded to the workpiece A1, creating thermal contact after coming into contact with the workpiece A1. In one embodiment, the adhesive 20 and the colloid used to form the retaining wall structure A11 may be adhesives of different materials. It should be noted that, when the adhesive 20 is a liquid adhesive, the function of the retaining wall structure A11 is to prevent the adhesive 20 from flowing to the outer side of the workpiece A1 or into the lower jig 11. In other embodiments, as shown in FIGS. 4A and 4B, adhesive 20′ is a solid sheet-type adhesive that becomes liquid at its working temperature. To prevent the adhesive 20′ from flowing out to the outer side of the workpiece A1 or the lower jig 11 once it turns liquid, the design of the retaining wall structure A11 can be used to block it. Therefore, as shown in FIG. 4A, when the adhesive 20′ is in its solid sheet form, step S12 may also include a step of using a suction head 131 on the upper jig 13 to pick up the sheet-type adhesive (adhesive 20′) to the surface of the workpiece A1.

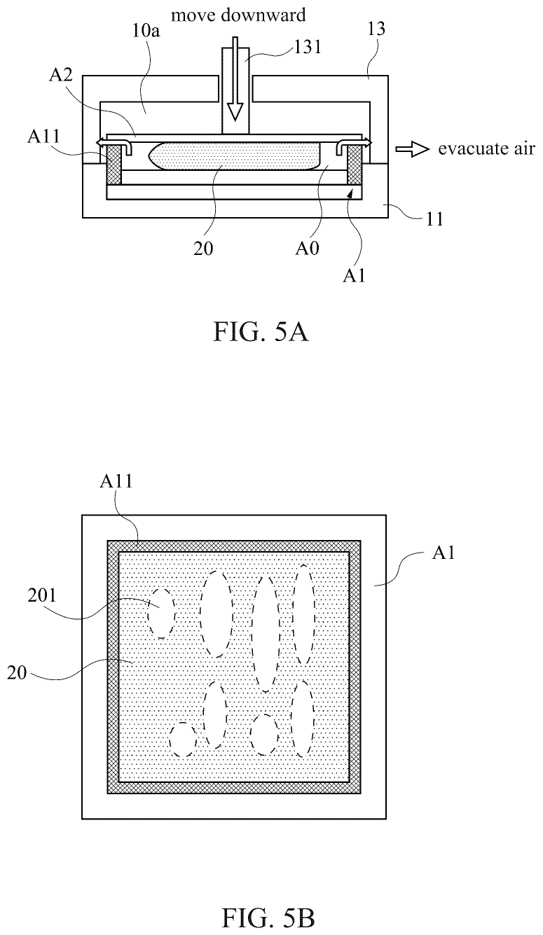

As shown in FIG. 5, after the completion of step S12, step S13 is performed. After the suction head 131 on the upper jig 13 picks up the heat sink A2, the upper jig 13 is moved to assemble with the lower jig 11 to form a first closed space 10a. Specifically, the suction head 131, which is mounted on the upper jig 13, can be connected to a negative pressure source to generate suction and can be driven to move up and down relative to the lower jig 11. The first closed space 10a is formed by the combination of the upper jig 13 and the lower jig 11, with the heat sink A2 and the workpiece A1 positioned inside. In one embodiment, as shown in FIG. 5, the upper jig 13 can be aligned and joined with the lower jig 11 through multiple guiding pillars 161. Once the upper jig 13 and the lower jig 11 are assembled, they can be further locked to ensure a tight seal between the upper jig 13 and the lower jig 11. Additionally, a groove 162 may be provided on the surface where the lower jig 11 and the upper jig 13 connect, allowing the installation of a sealing ring. This ensures a firm connection between the upper jig 13 and the lower jig 11, thereby completely sealing the first closed space 10a.

After step S13, step S14 is performed. As shown in FIG. 5A, the first closed space 10a is evacuated to create a first negative pressure environment. As shown in FIG. 8, the upper jig 13 is equipped with a negative pressure connector 132 to extract air from the first closed space 10a. However, in other embodiments, the negative pressure connector 132 may be positioned elsewhere in the jig assembly 10. Once the first negative pressure environment is established in the first closed space 10a, step S15 is performed. In step S15, the suction head 131 is driven to move toward the workpiece A1, positioning the heat sink A2 to an upper surface of the retaining wall structure A11, forming a second closed space A0 between the heat sink A2 and the workpiece A1, where the adhesive 20 is positioned within the second closed space A0 (as shown in FIG. 5A). Next, step S16 is performed, in which the suction head 131 continues to move toward the workpiece A1, causing the heat sink A2 to compress the retaining wall structure A11, which deforms the retaining wall structure A11 and forms a second negative pressure environment in the second closed space A0. Specifically, the surface of the heat sink A2 is rough. During the deformation of the retaining wall structure A11, the air in the second closed space A0 is discharged from between the heat sink A2 and the retaining wall structure A11 into the first closed space 10a. As the air in the first closed space 10a is evacuated to the outside, the second closed space A0 forms a second negative pressure environment.

It should be noted that the negative pressure environment referred to here, including the first negative pressure environment and the second negative pressure environment, both refer to pressures lower than the external ambient air pressure, but greater than or equal to 0 atm. For example, when the external ambient air pressure is 1 atm, the pressure in the negative pressure environment is preferably less than 1 atm, but greater than or equal to 0 atm. Similarly, if the external ambient air pressure is 1.2 atm, the pressure in the negative pressure environment is preferably less than 1.2 atm, but greater than or equal to 0 atm. Specifically, the pressure of the formed negative pressure environment can either be fixed or adjusted according to the properties of the adhesive material. In the present application, the pressures in both the first negative pressure environment and the second negative pressure environment are lower than the pressure of the external environment. In some embodiments, the pressure in the first negative pressure environment is higher than that in the second negative pressure environment, thus forming a pressure gradient from the external environment through the first negative pressure environment toward the second negative pressure environment. In other embodiments, the pressure in the first negative pressure environment and the pressure in the second negative pressure environment are equal, thus forming a pressure gradient from the external environment toward both the first negative pressure environment and the second negative pressure environment, but this is not intended to be limiting.

After step S16, step S17 is then performed to continue driving the suction head 131 to move toward the workpiece A1, thereby bonding the heat sink A2 to the workpiece A1. During the bonding process of the heat sink A2, as shown in FIGS. 5A and 5B, air may become enclosed within the adhesive 20 during the compression of the adhesive 20, leading to the formation of at least one gap 201 between the heat sink A2 and the workpiece A1. Next, step S18 is performed, where the suction head 131 is further driven toward the workpiece A1, applying pressure to the heat sink A2 and the adhesive 20, creating a negative pressure within the gap 201. In one embodiment, the rate at which the suction head 131 moves toward the workpiece A1 is inversely proportional to the viscosity of the adhesive 20, thereby ensuring even distribution of the adhesive 20 between the heat sink A2 and the workpiece A1.

It should be noted that the step of evacuating the first closed space 10a (i.e., step S14) and the steps of driving the suction head 131 to move toward the workpiece A1 (i.e., step S15, step S16, step S17 and step S18) are performed sequentially. Specifically, after the first closed space 10a creates a negative pressure environment, the heat sink A2 is pressed against the workpiece A1, causing the retaining wall structure A11 to deform, followed by bonding. However, this sequence is not intended to limit the present invention. In other embodiments, the above steps may be performed simultaneously. Specifically, after the upper jig 13 is moved to assemble with the lower jig 11 to form the first closed space 10a (i.e., step S12), the first closed space 10a can be evacuated (i.e., step S14) while the heat sink A2 is moved to compress the retaining wall structure A11, thereby pressing the adhesive 20 and the workpiece A1 (i.e., step S15, step S16, step S17 and step S18). Whether these steps are performed sequentially or simultaneously, it can be ensured that during the process of pressing the heat sink A2 onto the workpiece A1, the retaining wall structure A11 deforms, creating a negative pressure in the second closed space A0 and within gap 201.

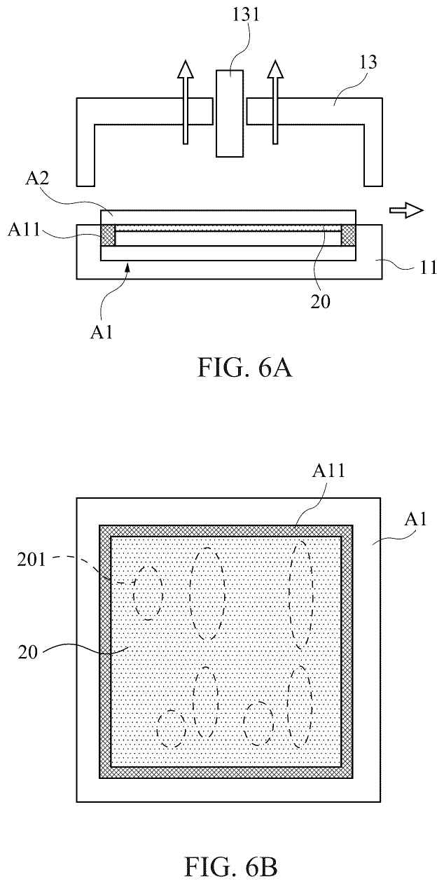

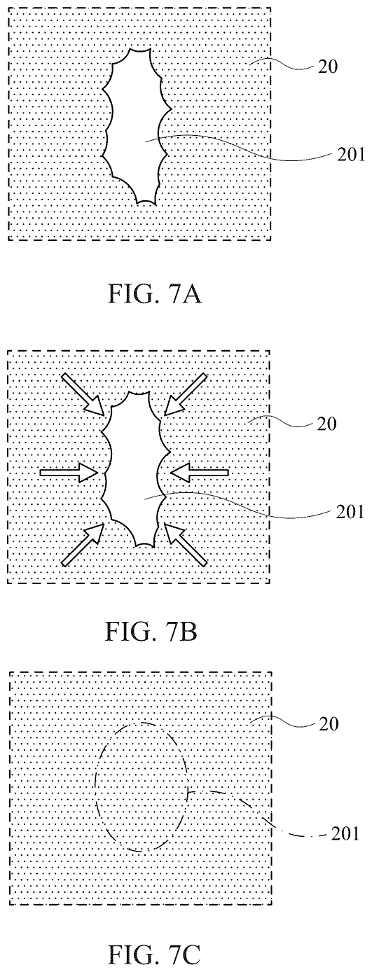

After the heat sink A2 is bonded to the workpiece A1 and a negative pressure forms within the gap 201, step S19 is then performed to restore the first negative pressure environment and the second negative pressure environment to normal pressure to complete the bonding process. As shown in FIG. 7A, when the heat sink A2 continues to press against the adhesive 20 and the workpiece A1, the compression of the adhesive 20 creates a negative pressure inside the gap 201. Once the negative pressure environment returns to normal atmospheric pressure, the principle of pressure flows from high to low causes the adhesive 20 to fill the gap 201, as shown in FIG. 7B. Finally, the gap 201 is completely filled with adhesive 20 (as shown in FIGS. 6B and 7C). In the present embodiment, as shown in FIG. 6A, the workpiece A1 with the bonded heat sink A2 can be returned to a normal pressure environment by separating the upper jig 13 from the lower jig 11. Specifically, the upper jig 13 and the suction head 131 can be removed together from the lower jig 11, allowing the suction head 131 to stop applying pressure to the heat sink A2 as normal atmospheric pressure is restored. By directly separating the upper jig 13 from the lower jig 11 to restore normal atmospheric pressure, the overall operation process can be simplified, improving operational efficiency.

In other embodiments, the upper jig 13 may first be moved from the lower jig 11 while the suction head 131 continues to exert pressure on the heat sink A2. That is, when the negative pressure environment is restored to normal atmospheric pressure, the suction head 131 maintains pressure on the heat sink A2, ensuring more stable adhesion between the heat sink A2 and the workpiece A1.

As shown in FIG. 6A, after the heat sink A2 is bonded to the workpiece A1, the height of the retaining wall structure A11 after deformation corresponds to the thickness of the adhesive 20. This occurs because, when the retaining wall structure A11 is deformed under the pressure of the heat sink A2, the heat sink A2 continues to compress the adhesive 20 until a uniform adhesive layer is formed between the heat sink A2 and the workpiece A1. Therefore, the initial design height of the retaining wall structure A11 must take the properties of the adhesive 20 into account to ensure that a uniform adhesive thickness is achieved after deformation. Specifically, when the adhesive is a liquid adhesive, the initial height of the retaining wall structure A11, before it deforms, should be designed to be slightly higher than the surface of the adhesive. Furthermore, the retaining wall structure A11 should have sufficient deformability, allowing it to effectively deform under pressure so that the heat sink can compress the adhesive, ensuring a uniform adhesive thickness. In other embodiments, when the adhesive is a sheet-type adhesive, the initial height of the retaining wall structure A11, before it deforms, should be designed to be slightly lower than a surface of the sheet-type adhesive. This ensures that under pressure, the adhesive thickness and the height of the retaining wall structure A11 will eventually become level.

In one embodiment, as shown in FIG. 1 and FIG. 8, in step S11, a product fixture 15 may be selected based on the size of the workpiece A1 and placed in the lower jig 11 to securely position the workpiece A1. Specifically, the product fixture 15 has a bearing groove 151, the size of which corresponds to the dimensions of the workpiece A1, ensuring that the workpiece A1 is securely held in place. The product fixture 15 and the lower jig 11 can be fixed together using a positioning structure 17. In one embodiment, the positioning structure 17 includes at least two protruding structures 171 and at least two recessed structures 172 that correspond to the protruding structures 171.

In the embodiment of FIG. 8, the protruding structure 171 can be a convex pillar disposed on the lower jig 11, while the recessed structure 172 can be a groove or a hole located on the product fixture 15. The product fixture 15 is precisely positioned using the positioning structure 17, ensuring that the center of the bearing groove 151 aligns with the center of the lower jig 11. This ensures that the bearing groove 151 holds the workpiece A1 in the center. As a result, the heat sink A2 can be evenly stressed during the bonding process, preventing displacement and improving the bonding quality between the heat sink A2 and the workpiece A1. In other embodiments, the dispositions of the protruding structure 171 and the recessed structure 172 are not limited to the configuration described above. Specifically, the protruding structure 171 can also be disposed on the product fixture 15, while the recessed structure 172 can be disposed on the lower jig 11, achieving the same precise positioning effect.

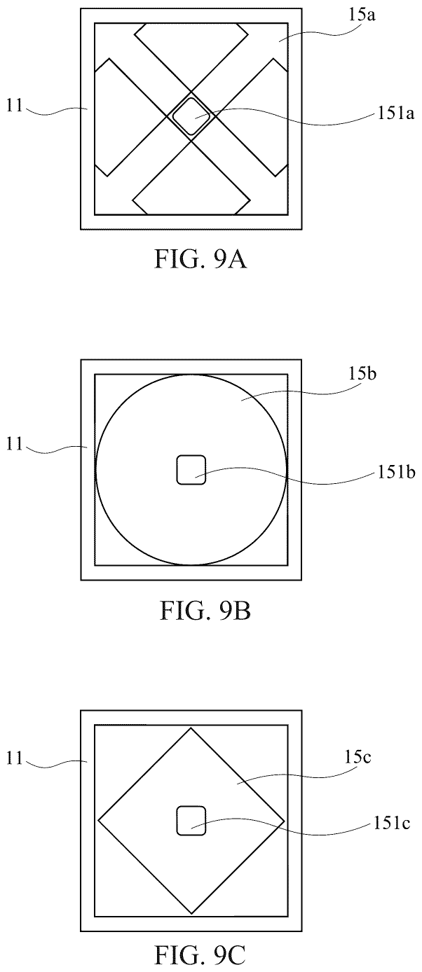

It should be noted that in the embodiment of FIG. 8, the cross-shaped structure of the product fixture 15 is shown for demonstration purposes only. In other embodiments, the product fixture 15 can be designed in different shapes according to specific requirements. For example, product fixture 15a may have an X-shaped structure as shown in FIG. 9A, product fixture 15b may have a circular structure as shown in FIG. 9B, or product fixture 15c may have a rectangular structure as shown in FIG. 9C. In one embodiment, the shape of the product fixture 15 and the shape of the lower jig 11 can be designed to be different, as long as at least three points on the sides of the product fixture 15 abut the inner wall of the lower jig 11 for proper positioning. In other words, the edges of the product fixture 15 do not need to be in full contact with the inner wall of the lower jig 11, which makes it easier for the user to replace or remove the product fixture 15. In some embodiments, a bearing groove 151a of the product fixture 15a, a bearing groove 151b of the product fixture 15b, and a bearing groove 151c of the product fixture 15c can be designed to accommodate different sizes of the workpiece A1.

As described in the above embodiments, the method for bonding the heat sink in a multi-negative pressure environment provided by the present invention primarily involves creating two separate negative pressure environments in two closed spaces and applying pressure to the adhesive in these negative pressure environments. This method efficiently resolves the issue of gaps forming between the heat sink and the workpiece, ensuring a high bonding quality. In addition, the design of the retaining wall structure can effectively prevent adhesive overflow, further ensuring the bonding quality. This method is particularly applicable to precision processes, such as those used in semiconductor manufacturing, with advantages such as simplified operation, increased efficiency, and reduced production costs.

Although the present invention has been described in detail with reference to certain embodiments, other variations are possible. Therefore, the spirit and scope of the appended claims should not be limited to the description of the embodiments contained herein. It will be apparent to those skilled in the art that various modifications can be made to the structure of the present invention without departing from the scope or spirit of the invention. In view of the foregoing, it is intended that the present invention covers modifications and variations of this invention, provided they fall within the scope of the following claims.

1. A method for bonding a heat sink in a multi-negative pressure environment wherein the method comprises steps of:
placing a workpiece to be processed in a lower jig, wherein a retaining wall structure is provided on a side edge of the workpiece;
supplying an adhesive to a surface of the workpiece within an area surrounded by the retaining wall structure;
after a suction head of an upper jig picks up the heat sink, moving the upper jig to assemble with the lower jig to form a first closed space, wherein the heat sink and the workpiece are positioned within the first closed space;
evacuating the first closed space to create a first negative pressure environment;
driving the suction head to move toward the workpiece, and positioning the heat sink to an upper surface of the retaining wall structure, forming a second closed space between the heat sink and the workpiece, wherein the adhesive is positioned within the second closed space;
continuing to drive the suction head to move toward the workpiece to compress the retaining wall structure, which causes deformation of the retaining wall structure and forms a second negative pressure environment in the second closed space;
continuing to drive the suction head to move toward the workpiece to bond the heat sink to the workpiece, wherein at least one gap is formed between the heat sink and the adhesive;
continuing to drive the suction head toward the workpiece to apply pressure to the heat sink after the gap is formed, thereby creating a negative pressure within the gap; and
restoring both the first negative pressure environment and the second negative pressure environment to normal atmospheric pressure after bonding the heat sink to the workpiece, allowing the adhesive surrounding the gap to fill the gap.

2. The method for bonding a heat sink in a multi-negative pressure environment according to claim 1, wherein a surface of the heat sink is rough, and during the deformation of the retaining wall structure, air in the second closed space can be discharged from between the heat sink and the retaining wall structure.

3. The method for bonding a heat sink in a multi-negative pressure environment according to claim 1, wherein the adhesive is a sheet-type adhesive, and an initial height of the retaining wall structure before deformation is lower than a top surface of the sheet-type adhesive.

4. The method for bonding a heat sink in a multi-negative pressure environment according to claim 1, wherein the adhesive is a liquid adhesive, and an initial height of the retaining wall structure before deformation is higher than a surface of the liquid adhesive.

5. The method for bonding a heat sink in a multi-negative pressure environment according to claim 1, the pressures in both the first negative pressure environment and the second negative pressure environment are lower than the pressure of an external environment, and the pressure in the first negative pressure environment is greater than or equal to the pressure in the second negative pressure environment.

6. The method for bonding a heat sink in a multi-negative pressure environment according to claim 1, the adhesive is a sheet-type adhesive, and the step of supplying the adhesive to the surface of the workpiece further includes using the suction head of the upper jig to pick up the sheet-type adhesive to the surface of the workpiece.

7. The method for bonding a heat sink in a multi-negative pressure environment according to claim 1, the step of evacuating the first closed space and the step of driving the suction head to move toward the workpiece are performed sequentially or simultaneously.

8. The method for bonding a heat sink in a multi-negative pressure environment according to claim 1, wherein the step of placing the workpiece in the lower jig comprises selecting a product fixture corresponding to the size of the workpiece and positioning the product fixture in the lower jig.

9. The method for bonding a heat sink in a multi-negative pressure environment according to claim 8, wherein the product fixture comprises a bearing groove, and when the product fixture is positioned in the lower jig by a positioning mechanism, the center of the bearing groove is aligned with the center of the lower jig.

10. The method for bonding a heat sink in a multi-negative pressure environment according to claim 9, wherein the positioning mechanism comprises at least two protruding structures and at least two recessed structures corresponding to the protruding structures, wherein the protruding structures are arranged on one of the product fixture and the lower jig, and the recessed structures are arranged on the other of the product fixture and the lower jig.
